(19) United States
(12) Patent Application Publication
(10) Pub. No.: US 2026/0245614 A1
(43) Pub. Date: Aug. 20, 2026

(54) APPARATUS WITH EARLY LIO PRECHARGE OPERATION

(71) Applicant: Micron Technology, Inc., Boise, ID (US)

(72) Inventors: Kenji Asaki, Sagamihara-shi (JP); Tetsuro Hara, Osaka-shi (JP); Yoshifumi Mochida, Sagamihara (JP)

(21) Appl. No.: 19/532,121

(22) Filed: Feb. 6, 2026

Related U.S. Application Data
(60) Provisional application No. 63/760,481, filed on Feb. 19, 2025.

(51) Int. Cl. G11C 11/4096; G11C 11/4076; G11C 11/4091

(52) U.S. Cl. CPC G11C 11/4096; G11C 11/4076; G11C 11/4091

(57) ABSTRACT

Some embodiments of the disclosure provide an apparatus comprising a sense amplifier to sense and amplify data read from a memory cell through a bit line BL and a local input/output line LIO to receive the amplified read data which is then transferred to for example a main input/output line and to data terminals. LIO is precharged to a high voltage level, such as VPERI, prior to threshold voltage compensation of the sense amplifier in response to an Active signal rather than a Sense signal. The early LIO precharge can prevent or mitigate the LIO and BL capacitive coupling noise to sensing, and improve the sense margin.

### CROSS-REFERENCE TO RELATED APPLICATIONS

This application claims the filing benefit of U.S. Provisional Application No. 63/760,481, filed February 19, 2025. This application is incorporated by reference herein in its entirety and for all purposes.

### BACKGROUND

High data reliability, high speed of memory access, low power consumption, and reduced chip size are some features that are demanded from semiconductor memory devices, such as a dynamic random-access memory (DRAM). A memory device may include a plurality of memory cells located at intersections of word lines arranged in rows and bit lines arranged in columns. Each memory cell may include a capacitor to store data and a transistor to access the capacitor. A memory device may further include sense amplifiers that sense and amplify data read from memory cells of bit lines on associated columns of a selected row. The amplified read data may be transferred to input/output lines to be output from external data terminals.

### BRIEF DESCRIPTION OF THE DRAWINGS

FIG. 1 is a block diagram of an example semiconductor device according to some embodiments of the disclosure.

FIG. 2A shows example local input/output line connection of sense amplifiers and sub-amplifiers of an example apparatus according to some embodiments of the disclosure.

FIG. 2B is a circuit diagram of at least part of an example sub-amplifier according to some embodiments of the disclosure.

FIG. 3 is a schematic diagram of at least part of an example apparatus according to some embodiments of the disclosure.

FIG. 4 is a timing diagram of an early LIO precharge operation according to some embodiments of the disclosure.

### DETAILED DESCRIPTION

Various example embodiments of the disclosure and combinations thereof will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for ease of illustration. In the drawings, the dimensions and dimensional ratios of each unit do not necessarily match the actual dimensions and dimensional ratios in the embodiments.

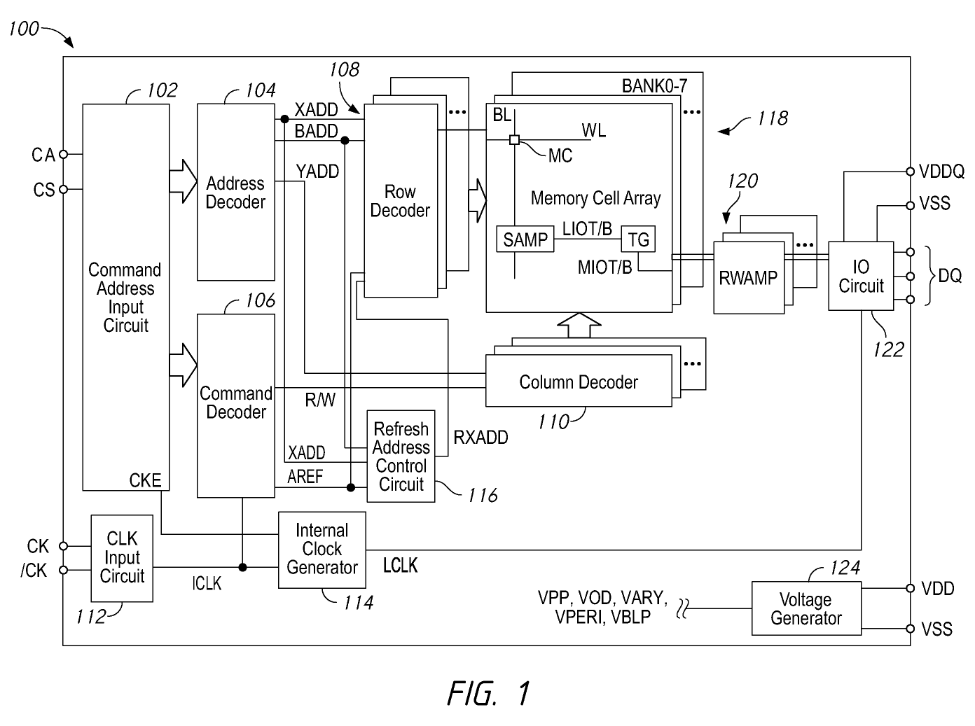

FIG. 1 is a block diagram of an example semiconductor device 100 according to some embodiments of the disclosure. The semiconductor device 100 may be one example of an apparatus. The semiconductor device 100 may be a semiconductor memory device, such as a dynamic random access memory (DRAM). The semiconductor device 100 includes a memory array 118. The memory array 118 is shown as including a plurality of memory banks. In the depicted example, the memory array 118 is shown as including eight memory banks BANK0-BANK7. More or fewer banks may be included in the memory array 118. Each memory bank includes a plurality of word lines WL, a plurality of bit lines BL (or digit lines DL), and a plurality of memory cells MC arranged at intersections of the plurality of word lines WL and the plurality of bit line BL. Selection of the word line WL is performed by a row decoder 108 and selection of the bit lines BL is performed by a column decoder 110. In the depicted example, the row decoder 108 includes a respective row decoder for each memory bank and the column decoder 110 includes a respective column decoder for each memory bank. The bit lines BL are coupled to a respective sense amplifier SAMP of the memory array 118. Read data from the bit line BL is amplified by the sense amplifier SAMP, and transferred to a respective read/write amplifier (RWAMP) 120 for each memory bank over complementary local input/output data lines LIOT/B (LIO True/Bar (False)), a transfer gate TG, and complementary main input/output data lines MIOT/B (MIO True/Bar (False)) which are coupled to RWAMP 120. Conversely, write data outputted from RWAMP 120 for each memory bank is transferred to the sense amplifier SAMP over the complementary main input/output data lines MIOT/B, the transfer gate TG, and the complementary local input/output data lines LIOT/B, and written in the memory cell MC coupled to the bit line BL.

The semiconductor device 100 may employ a plurality of external terminals. The external terminals may include command and address (CA) terminals coupled to a command and address bus to receive commands and addresses and a chip select (CS) signal, clock terminals to receive clocks CK and /CK, data terminals DQ to provide data, and power supply terminals to receive power supply potentials VDD, VSS, and VDDQ.

The clock terminals are supplied with external clocks CK and /CK that are provided to an input circuit 112. The external clocks CK and /CK may be complementary. The input circuit 112 generates an internal clock ICLK based on the CK and /CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal clocks LCLK are provided to an input and output (IO) circuit 122 to time operation of circuits included in the IO circuit 122, for example, to data receivers to time the receipt of write data. In some embodiments, the internal clocks LCLK may include a read clock which is used to control the timing of read operations, and a write clock which is used to control the timing of write operations. In some embodiments, the internal clocks may be passed to the IO circuit 122. In some embodiments, the internal clocks may also be passed to internal components, such as RWAMP 120.

The CA terminals may be supplied with memory addresses. The memory addresses supplied to the CA terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The CA terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to the command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line.

The semiconductor device 100 may receive an access command which is a read command. When a read command is received, and a bank address, a row address and a column address are timely supplied with an activate command and the read command, read data is read from memory cells in the memory array 118 corresponding to the row address and column address. The read command is received by the command decoder 106, which provides internal commands so that the read data from the memory cells in the memory array 118 is provided to RWAMP 120. The read data is output to outside the semiconductor device 100 from the data terminals DQ via the IO circuit 122.

The semiconductor device 100 may receive an access command which is a write command. When the write command is received, and a bank address, a row address and a column address are timely supplied with an activate command and the write command, write data is supplied through the DQ terminals to RWAMP 120. The write data supplied to the data terminals DQ is written to the memory cells in the memory array 118 corresponding to the row address and column address. The write command is received by the command decoder 106, which provides internal commands so that the write data is received by data receivers in the IO circuit 122. Write clocks may also be provided to the external clock terminals for timing the receipt of the write data by the data receivers of the IO circuit 122. The write data is supplied via the IO circuit 122 to RWAMP 120.

The semiconductor device 100 may also receive commands causing it to carry out one or more refresh operations as part of a self-refresh mode. In some embodiments, the self-refresh mode command may be externally issued to the semiconductor device 100. In some embodiments, the self-refresh mode command may be periodically generated by a component of the device. In some embodiments, when an external signal indicates a self-refresh entry command, the refresh signal AREF may also be activated.

The power supply terminals are supplied with power supply potentials VDD and VSS. The power supply potentials VDD and VSS are supplied to an internal voltage generating circuit 124. The internal voltage generating circuit 124 generates various internal potentials, such as VPP, VOD, VARY, VPERI, VBLP, and the like, based on the power supply potentials VDD and VSS, for supplying various voltages to be used in the semiconductor device 100. VPP may be used in the row decoder 108. VOD and VARY may be used in the sense amplifiers SAMP in the memory array 118. VPERI may be used in peripheral circuit blocks. VBLP may be a precharge voltage with a half-level potential or an intermediate potential. For example, while VDD may be 1.1V or 1.2V and VSS may be 0V (ground reference), VPERI may be set to the same level as or higher than VDD. Also, while VARY may be equal to or less than 1.0V, VBLP may be set to around half of VARY (VARY/2) that is equal to or less than 0.5V. The internal potentials and their values are not limited to those described herein and may include other potentials and values as appropriate. The internal voltage generating circuit 124 may also be referred to as an internal voltage generator. The internal voltage generating circuit 124 may include a charge pump circuit.

The power supply terminals are also supplied with power supply potential VDDQ. The power supply potential VDDQ is supplied to the IO circuit 122. The power supply potential VDDQ may be the same potentials as the power supply potential VDD in one embodiment of the disclosure. The power supply potential VDDQ may be different potentials from the power supply potential VDD in another embodiment of the disclosure. The power supply potential VDDQ are used for the IO circuit 122 so that power supply noise generated by the IO circuit 122 does not propagate to the other circuit blocks.

For the sense operation by a sense amplifier (hereinafter referred to as SAMP) during the data read operation, in some instances, a local input/output line or a complementary local input/output line pair (hereinafter referred to as LIO or LIOT/B) which is initially precharged to a low precharge voltage level such as VBLP before sensing may be further precharged to a high precharge voltage level such as VPERI at a later timing. This helps improve sensing speed and readout performance. More specifically, for example, during the initial precharge phase before sensing, LIOT and LIOB are charged and equalized to VBLP by one or more precharge and equalization transistors responsive to an initial control signal, and then, during the next, boost precharge phase, LIOT and LIOB are raised to VPERI by one or more separate precharge and equalization transistors, which are supplied with VPERI, responsive to another control signal. The timing of the boost precharging may occur at or immediately after the sense timing of read data from a bit line BL (or a digit line DL) by SAMP. However, since LIO and BL are capacitively coupled, prechaging the LIO to the higher precharge level at the above timing may become noise to sensing. Even a few mV of capacitive coupling can result in a loss of several tens of mV of cell data. As the sense margin (e.g., in voltage) becomes smaller due to process miniaturization and chip/device size reduction, it is important to prevent or mitigate such noise. In some instances, LIO precharge to the higher precharge level may be performed at a sufficiently later timing than the sense timing to address the noise issue. This late LIO precharge, however, may have an undesirable effect to tRCD, i.e., Row Column Delay or Row Address Strobe (RAS) to Column Address Strobe (CAS) Delay. tRCD defines the number of clock cycles between activating a row and accessing columns of that row. The late LIO precharge may increase the delay time or the latency between RAS and CAS. Therefore, in some instances, to address the above noise issue to sensing without affecting tRCD, LIO precharge may be performed prior to threshold voltage compensation (hereinafter referred to as VtC) of SAMP. More specifically, for example, a timing signal for LIO precharge may be synchronized with activation rather than sensing to cause LIO precharge to take place before VtC. With this early LIO precharge, while noise may be carried on BL prior to VtC, the impact of this noise on sensing may be minimal or negligible since VtC takes place after the LIO precharge. VtC compensates for a threshold volage Vt mismatch between components, such as transistors, of SAMP, and is typically performed immediately after the activation but well before the sensing. The timing of VtC is pre-determined. A VtC circuit (not separately depicted herein) may be any circuit capable of performing the SAMP VtC operation.

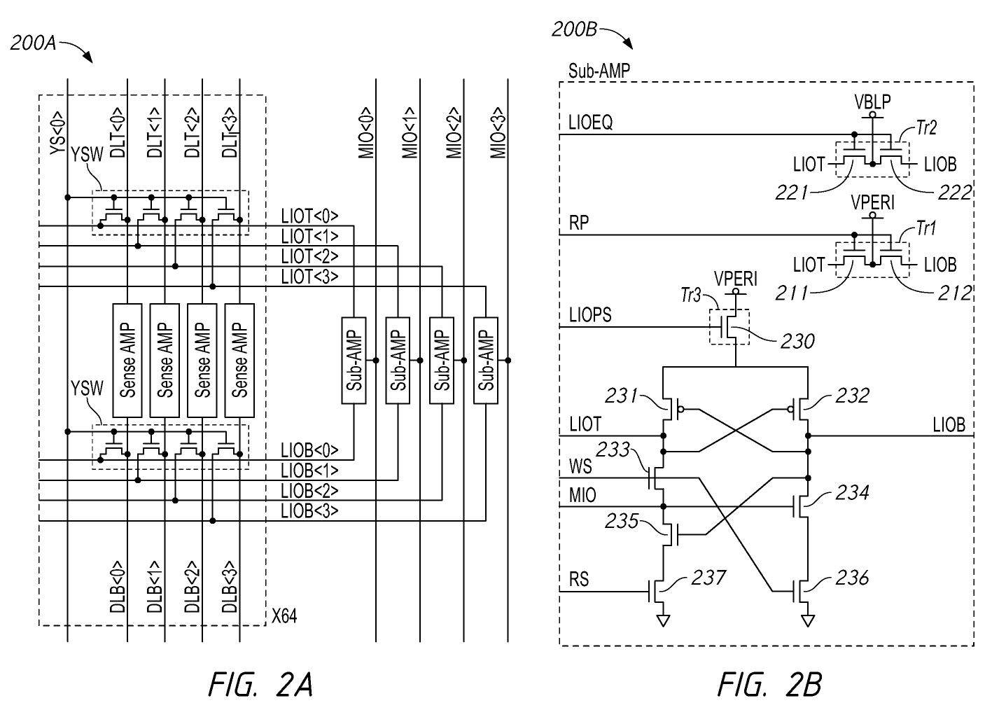

FIG. 2A shows example LIOT/B connection of sense amplifiers and sub-amplifiers of an example apparatus 200A according to some embodiments of the disclosure. FIG. 2B is a circuit diagram of at least part of an example sub-amplifier 200B according to some embodiments of the disclosure. The apparatus 200A and the sub-amplifier 200B may be included in the semiconductor device 100 of FIG. 1. The sub-amplifier 200B may be included in the transfer gate TG of the semiconductor device 100. The apparatus 200A includes sense amplifiers SAMPs coupled to respective pairs of complementary digit (bit) lines (hereinafter referred to as DLT/B) and respective pairs of LIOT/B through a column switch YSW. The column switch YSW includes a plurality of transistors that are coupled to the respective LIOT/Bs on one side and the respective DLT/Bs on another side via corresponding source/drain transistor terminals. The column switch YSW is controlled by, for example, a column select signal YS that may include a column address. The column select signal YS and/or the column address may be included in external signals/commands supplied by an external device and may be decoded and provided by, for example, a column decoder (e.g., the column decoder 110 of the semiconductor device 100 in FIG. 1). Other decoders, control circuitry, or any combination thereof may provide the column select YS and/or the column address. When the column select signal YS including a certain column address turns High, a transistor in the column switch YSW corresponding to the selected column is activated and couples the associated LIOT/B and DLT/B. In the depicted example, the column switch YSW is provided to each of the DLT side and the DLB side.

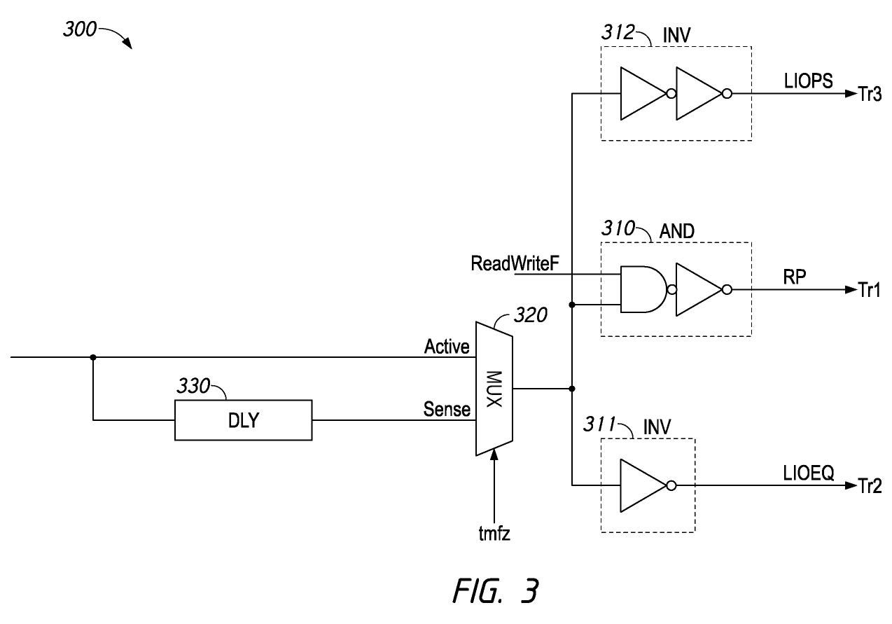

The apparatus 200A further includes sub-amplifiers (hereinafter referred to as Sub-AMP) coupled to respective pairs of LIOT/B on one side and respective main (or global) input/output lines (hereinafter referred to as MIO) on another side for coupling LIO and MIO and transferring the SAMP-amplified data between LIO and MIO. In the depicted example of FIG. 2B, each Sub-AMP 200B includes precharge transistors Tr1 and Tr2 for precharing LIOT/B. The precharge transistor Tr1 includes, for example, two transistors 211, 212 of a first type (e.g. n-type or n-channel field effect transistors (NFET), such as nMISFET or nMOSFET). The transistors 211 and 212 are coupled to each other on one side via corresponding source terminals and coupled to associated LIOT and LIOTB, respectively, on another side via drain terminals. Sources of the transistors 211 and 212 are supplied with a first precharge voltage, VPERI. Gates of the transistors 211 and 212 are coupled to a first control line (which may be referred to as a read precharge RP line) to receive a first control signal RP to precharge the LIOT/B pair to VPERI. Likewise, the precharge transistor Tr2 includes, for example, two transistors 221, 222 of the first type coupled to each other on one side via source terminals and coupled to associated LIOT and LIOTB, respectively, on another side via drain terminals. Sources of the transistors 221 and 222 are supplied with a second precharge voltage, VBLP. Gates of the transistors 221 and 222 are coupled to a second control line (which may be referred to as an LIO equalization EQ line) to receive a second control signal LIOEQ to maintain the LIOT/B pair at VBLP. VPERI and VBLP may be supplied by an internal voltage generator (e.g., the internal voltage generating circuit 124 of the semiconductor device 100 in FIG. 1). As described above with reference to FIG. 1, VPERI may be equal to or greater than VDD, and VBLP may be equal to or less than VARY/2, for example. The RP and LIOEQ control signals may be provided by an apparatus shown in FIG. 3 which will be described in detail below.

Besides the LIO precharge circuitry, Sub-AMP 200B in the depicted example includes amplifier circuitry and a power supply transistor Tr3. The power supply transistor Tr3 couples a power supply source of the amplifier circuitry to VPERI. The power supply transistor Tr3 may include one or more transistors 230. The transistor 230 is supplied with VPERI at its source and coupled to a control line (which may be referred to as an LIO power supply PS line) to receive a power supply control signal LIOPS. A drain of the transistor 230 is coupled to the amplifier circuitry.

The amplifier circuitry transfers the SAMP-amplified data from LIO to MIO. The configuration of the amplifier circuitry between LIO and MIO is not limited to the depicted example; the amplifier circuitry may have various circuit configurations. In the depicted example, the amplifier circuitry includes transistors 231, 232 of a second-type (e.g. p-type or p-channel field effect transistors (PFET), such as pMISFET or pMOSFET) on the power supply source side. The transistors 231 and 232 have sources coupled to the drain of the transistor 230 to receive VPERI in response to gate signals. A drain of the transistor 231 is coupled to LIOT, which in turn is coupled to a gate of the transistor 232 and a source of a transistor 233 of the first type. The transistor 233 receives a gate control signal WS (which may also be referred to as a write select or a write switch). A drain of the transistor 233 is coupled to MIO and a source of a transistor 235 of the first type. A drain of the transistor 235 is coupled to a source of a transistor 237 of the first type. A drain of the transistor 237 is coupled to a signal ground/reference. The transistor 237 receives a gate control signal RS (which may also be referred to as a read select or a read switch). A drain of the transistor 232 is coupled to LIOB, which in turn is coupled to a gate of the transistor 231, a source of a transistor 234 of the first type, and a gate of the transistor 235. A gate of the transistor 234 is coupled to MIO. A drain of the transistor 234 is coupled to a source of a transistor 236 of the first type. The transistor 236 receives the gate control signal WS. A drain of the transistor 236 is coupled to the signal ground/ reference. The amplifier circuitry between LIO and MIO in the sub-amplifier may have any configuration for coupling LIO and MIO and transferring the SAMP-amplified data between LIO and MIO other than the above-described configuration.

While in the depicted example, the sub-amplifier includes the LIO precharge circuitry including the precharge transistors Tr1 and Tr2, in other instances, the LIO precharge circuitry may be provided separately from the sub amplifier. For example, the LIO precharge circuity may be provided in the sense amplifier or may be separate circuitry coupled between the sense amplifier and the sub-amplifier.

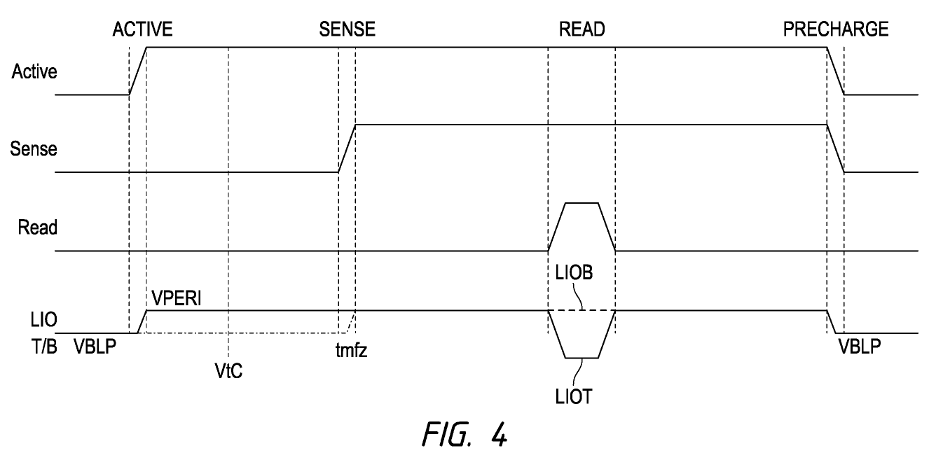

FIG. 3 is a schematic diagram of at least part of an example apparatus 300 according to some embodiments of the disclosure. FIG. 4 is an example timing diagram of an early LIO precharge operation according to some embodiments of the disclosure. The apparatus 300 implements the early LIO precharge scheme according to some embodiments of the disclosure. The apparatus 300 may be included in the semiconductor device 100 in FIG. 1, for example. The apparatus 300 controls the LIO prechage operation of precharge transistors (e.g., the precharge transistors Tr1 and Tr2 of the sub-amplifier 200B in FIG. 2).

The apparatus 300 includes a first signal path to provide a read-prechage (RP) control signal and a second signal path to provide a LIO equalization (LIOEQ) control signal. The first and second signal paths may be coupled to the precharge transistors Tr1 and Tr2 of the sub-amplifier 200B in FIG. 2, respectively. The apparatus 300 includes an AND circuit 310 on the first signal path to provide an output signal as the LIOEQ control signal to the precharge transistor Tr1, and an inverter INV circuit 311 on the second signal path to provide an output signal as the RP control signal to the precharge transistor Tr2. The apparatus 300 of the depicted example further includes a third signal path to provide a LIO power supply (LIOPS) control signal. The third signal path may be coupled to the power supply transistor Tr3 of the sub-amplifier 200B in FIG. 2. The apparatus 300 includes an inverter INV circuit 312 on the third signal path to provide its output signal as the LIOPS control signal to the power supply transistor Tr3. The circuit configuration of each of the AND circuit 310, the inverter INV circuit 311, and the inverter INV circuit 312 is not limited to the depicted example; each circuit may have any configuration including other circuit elements as appropriate. In the depicted example, the AND circuit 310 includes a NAND gate and an inverter coupled to each other in series, the NAND gate having inputs to receive an output signal from a multiplexer MUX 320 (which will be described in detail later) and a signal (ReadWriteF) that stays Low for a certain period of time during read and write operations, the inverter receiving an output of the NAND gate and outputting the inversed signal as the RP control signal. This configuration is, however, only one example. The same goes for the inverter INV circuits 311 and 312.

The apparatus 300 further includes a multiplexer MUX 320 and a delay circuit DLY 330. The multiplexer MUX 320 are coupled to, on the output side, the AND circuit 310, the inverter circuit INV 311, and the inverter circuit INV 312 on the first, second, and third signal paths/lines. The multiplexer MUX 320 receives an Active signal and a Sense signal on the input side. The Active signal may be an activation timing signal to activate a target row of a memory cell array for the read operation. The Sense signal may be a sense timing signal to enable SAMP and initiate the sense operation of the read data from the selected column on the activated row. The Active signal and the Sense signal may be included in external commands/signals supplied by an external device and may be decoded and provided by, for example, a row decoder (e.g., the row decoder 108 of the semiconductor device 100 in FIG. 1). Other decoders, control circuitry, or any combination thereof may provide the Active signal and the Sense signal. In some instances, a row decoder or other decoders/circuitry may include a timing controller circuit to provide an activation timing signal and a sense timing signal in response to various clock signals and command signals to control the timing.

In the depicted example, the delay circuit DLY 330 provided on a signal path of the Sense signal before the multiplexer MUX 320 adds a delay to the Sense signal. The delay circuit DLY 330 may be included in the timing controller circuit, for example. The delay circuit DLY 330 may have any circuit configuration capable of adding a delay to the Sense signal such that the sensing is initiated sufficiently after the LIO precharge, that is the LIO precharge timing is well before the sensing timing according to the early LIO precharge scheme. As one example, the delay may correspond to at least a period of time from SAMP VtC timing and row/word line enable timing until data/charge comes out from a memory cell of the enabled row. The Sense signal thus enables SAMP for the sense operation after the delay.

As shown in FIG. 4, the Active signal turns High sufficiently prior to the Sense signal turning High. The timing of the Active signal turning high is also prior to the initiation of threshold voltage compensation VtC of SAMP. The Active signal input to the multiplexer MUX 320 travels to the RP line via the AND circuit 310 and is provided to the gate of the precharge transistor Tr1 as the RP control signal. The Active signal also travels to the LIOEQ line via the inverter INV circuit 311 and is provided to the gate of the precharge transistor Tr2 as the LIOEQ control signal. Furthermore, the Active signal travels to the LIOPS line via the inverter INV circuit 312 and is provided to the gate of the power supply transistor Tr3 as the LIOPS control signal. As shown in FIG. 4, when the Active signal turns High, the precharge transistor Tr1 turns on in response to the RP control signal via the AND circuit 310 and the LIO (LIOT/B) is charged to VPERI by the precharge transistor Tr1, whereas the precharge transistor Tr2 that receives the inversed control signal via the inverter INV circuit 311 turns off. At the same time, the power supply transistor Tr3 turns on in response to the LIOPS control signal via the inverter INV circuit 312 and supplies VPERI to the amplifier circuitry of the sub-amplifier (see FIG. 2B). When the Active signal turns Low, while the precharge transistor Tr1 is turned off (and the power supply transistor Tr3 is off), the precharge transistor Tr2 turns on and the LIO is charged to VBLP by the precharge transistor Tr2 in response to the LIOEQ control signal inverted to High via the inverter INV circuit 311.

In the present embodiments, therefore, the LIO precharge is synchronized with the Active signal instead of the Sense signal. The LIO precharge is performed at least prior to the threshold voltage compensation VtC that takes place before sensing. This early LIO precharge according to the present embodiments can further effectively prevent or mitigate the noise due to the LIO and BL capacitive coupling and improves the sense margin, without any undesirable effect to tRCD. Therefore, an improvement in yield can be expected. Also, in the depicted example, the LIO voltage level of the early precharge is set to the high voltage level, VPERI. In other instances, precharging the LIO to a VSS level may be possible; however, since the column switch YSW receives the column select signal YS which is also at a VSS level, VSS may leak from the LIO to the BL through the column switch YSW, which may affect sensing. On the contrary, if LIO=VPERI as described above, the gate-source voltage Vgs of the column switch YSW becomes negative, and hence, there will be less off leakage at the column switch YSW.

Furthermore, according to the present embodiments, since the apparatus 200 includes the multiplexer MUX, the apparatus 200 can switch the LIO precharge operation between the activation synchronization mode and the sensing synchronization mode. For example, as shown in FIGS. 3 and 4, the multiplexer MUX may receive a control signal that indicates a test mode and/or a fuse mode (tmfz), and in response to the control signal tmfz, the multiplexer MUX may select the sensing synchronization mode which uses the Sense signal for the precharge operation. A delay is added to the Sense signal by the delay circuit DLY 330 such that the Sense signal turns to a high level at or after the sense timing. If the sense synchronization mode is selected, precharge of the LIO to VPERI takes place at or after the read data sense timing in response to the Sense signal turning High (see FIG. 4).

In the above descriptions, DRAM is merely one example, and the embodiments and the descriptions herein are not intended to be limited to DRAM. Memory devices other than DRAM, such as a static random-access memory (SRAM), a flash memory, an erasable programmable read-only memory (EPROM), a magnetoresistive random-access memory (MRAM), and a phase-change memory, can also be applied as the apparatuses of the present embodiments. Furthermore, devices other than memory, including logic ICs, such as a microprocessor and an application-specific integrated circuit (ASIC), are also applicable as the apparatuses according to the present embodiments.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still falling within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising a local input/output line (LIO) configured to transfer read data amplified by a sense amplifier of a memory cell, wherein the LIO line is precharged to a first voltage level from a second voltage level prior to threshold voltage compensation of the sense amplifier, the first voltage level higher than the second voltage level.

2. The apparatus according to claim 1, wherein the LIO is precharged in response to an active signal prior to the threshold voltage compensation.

3. The apparatus according to claim 2, further comprising a first transistor coupled to the LIO, wherein the first transistor is supplied with a first voltage and turns on in response to the active signal to charge the LIO to the first voltage level prior to the threshold voltage compensation.

4. The apparatus according to claim 3, further comprising a second transistor coupled to the LIO, wherein the second transistor is supplied with a second voltage and turns on in response to a sense signal to charge the LIO to the second voltage level at or after a sense operation, and the sense operation takes place after the threshold voltage compensation.

5. The apparatus according to claim 4, wherein the first transistor and the second transistor are commonly coupled to the LIO, and when the active signal turns high, the first transistor charges the LIO to the first voltage level.

6. The apparatus according to claim 5, wherein when the sense signal turns high, the second transistor charges the LIO to the second voltage level.

7. The apparatus according to claim 4, wherein
the first transistor and the second transistor are commonly coupled to the LIO,
a drain of the first transistor is coupled to the LIO, a source of the first transistor is supplied with the first voltage, and a gate of the first transistor is coupled to a first control line to receive the active signal, and
a drain of the second transistor is coupled to the LIO, a source of the second transistor is supplied with the second voltage, and a gate of the second transistor is coupled to a second control line to receive the sense signal.

8. The apparatus according to claim 4, further comprising a multiplexer configured to select the active signal or the sense signal.

9. The apparatus according to claim 8, further comprising a delay circuit on a signal path of the sense signal and configured to add a delay to the sense signal before the sense signal is input to the multiplexer.

10. The apparatus according to claim 1, wherein precharging the LIO is synchronized with activation of a sense target row of a memory cell array prior to the threshold voltage compensation.

11. An apparatus, comprising:
a memory cell;
a bit line coupled to the memory cell:
a sense amplifier coupled to the bit line;
a local input/output line (LIO) coupled to the sense amplifier; and
at least first and second precharge transistors coupled to each other in series and commonly coupled to the LIO, wherein
the first and second precharge transistors are supplied with first and second precharge voltages, respectively, the first precharge voltage higher than the second precharge voltage, and
the LIO is charged to the first precharge voltage when the first precharge transistor turns on in response to an active signal while the second precharge transistor is off prior to threshold voltage compensation of the sense amplifier.

12. The apparatus according to claim 11, wherein the first precharge transistor is supplied with the first precharge voltage at a source thereof, coupled to the LIO at a drain thereof, and coupled to a control line at a gate thereof, the control line configured to receive a control signal in response to the active signal.

13. The apparatus according to claim 11, wherein the LIO is charged to the second precharge voltage when the second precharge transistor turns on in response to a sense signal while the first precharge transistor is off.

14. The apparatus according to claim 13, wherein the second precharge transistor is supplied with the second precharge voltage at a source thereof, coupled to the LIO at a drain thereof, and coupled to a control line at a gate thereof, the control line configured to receive a control signal in response to the sense signal.

15. The apparatus according to claim 13, wherein the active signal activates a row of the memory cell for a read operation, and the sense signal initiates a sense operation.

16. The apparatus according to claim 13, further comprising a multiplexer coupled to at least the first and second precharge transistors and configured to select the active signal or the sense signal.

17. The apparatus according to claim 13, further comprising a delay circuit configured to delay the sense signal before the sense signal is input to the multiplexer.

18. An apparatus, comprising:
a sense amplifier configured to receive read data from a memory cell via a bit line of a selected column on an activated row and configured to amplify the read data; and
a local input/output line (LIO) configured to receive the amplified read data from the sense amplifier and configured to be charged to a first voltage level from a second voltage level in response to a control signal that turns high prior to threshold voltage compensation of the sense amplifier, the first voltage level higher than the second voltage level.

19. The apparatus according to claim 18, wherein the LIO is coupled to a precharge transistor which is supplied with the first voltage level, and is charged to the first voltage level when the precharge transistor turns on in response to the control signal.

20. The apparatus according to claim 18, wherein the first voltage level is a VPERI level.
